(19) United States
(12) Patent Application Publication
(10) Pub. No.: US 2007/0080351 A1
(43) Pub. Date: Apr. 12, 2007

(54) DISPLAY DEVICE

(76) Inventors: Miki MORI, Yokohama-shi (JP); Kaoru Koiwa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/609,350

(22) Filed: Dec. 12, 2006

Related U.S. Application Data
(63) Continuation of application No. PCT/JP05/11530, filed on Jun. 23, 2005.

(30) Foreign Application Priority Data
Jul. 7, 2004 (JP) 2004-200541

(51) Int. Cl. H01L 29/04

(52) U.S. Cl. 257/72

(57) ABSTRACT

A display device comprises a first substrate which has a line-forming surface, a second substrate which is arranged opposite to the line-forming surface by a gap interposed and has peripheral edge bonded to the first substrate, a plurality of display elements which are provided between the first substrate and the second substrate, a plurality of lines which are formed on the line-forming surface, extend to the peripheral edge of the line-forming surface and supply a drive voltage to the display elements, and a drive circuit substrate which is arranged at the peripheral edge of the line-forming surface and on which drive circuit is mounted.

### CROSS-REFERENCE TO RELATED APPLICATIONS

This is a Continuation Application of PCT Application No. PCT/JP2005/011530, filed Jun. 23, 2005, which was published under PCT Article 21(2) in Japanese.

This application is based upon and claims the benefit of priority from prior Japanese Patent Application No. 2004-200541, filed Jul. 7, 2004, the entire contents of which are incorporated herein by reference.

### BACKGROUND OF THE INVENTION

1. Field of the Invention

The present invention relates to a display device having a drive circuit.

2. Description of the Related Art

In recent years, flat-panel displays, in which a large number of electron emission elements face a fluorescent screen, have been developed. Known as flat-panel displays are a field emission display (hereinafter referred to as “FED”) and a surface-conduction electron-emitter display (hereinafter referred to as an “SED”). In the FED, electron emission elements emit electron beams to cause a fluorescent member to emit light. In the SED, surface-conduction electron-emitter elements emit electron beams to cause a fluorescent member to emit light are known as flat-panel displays.

Most SEDs have a front substrate and rear substrate opposing each other, with a predetermined gap between them. The substrates are bonded to each other, at their peripheries, via a rectangular frame-shaped sidewall interposed between them, providing a vacuum envelope. The vacuum envelope is highly evacuated to about 10⁻⁴ Pa or less. To withstand the atmospheric pressure applied to the front and rear substrates, a plurality of support members are provided between the substrates.

A fluorescent screen including fluorescent layers of red, blue and green is provided on the inner surface of the front substrate. A number of electron emission elements are provided on the inner surface of the rear substrate. The electron emission elements emit electrons, which excite the fluorescent layers. Thus excited, the fluorescent layers emit light. The electron emission elements and the fluorescent layers are provided in one-to-one relation, providing pixels. On the inner surface of the rear substrate, many scanning lines and many signal lines are arranged, forming a matrix pattern, and are connected to the electron emission elements. The scanning lines are connected, at one end, to a scanning-line drive circuit, and the signal lines are connected, at one end, to a signal-line drive circuit as disclosed in, for example, Jpn. Pat. Appln. KOKAI Publication No. 7-326284. The SED may have two scanning-line drive circuits and a signal-line scanning drive circuit. In this case, the scanning lines are connected at one end to one scanning-line drive circuit and at the other end to the other scanning-line drive circuit, and the signal lines are connected at one end to the signal-line drive circuit.

When driven, the scanning-line drive circuit applies a drive voltage to the scanning lines. When driven, the signal-line drive circuit applies a drive voltage to the signal lines. An anode voltage is thereby applied to the fluorescent screen. The anode voltage accelerates the electron beams emitted from the electron emission elements and collide with the fluorescent screen. As a result, the fluorescent layers emit light beams, displaying an image. In the SEC, the gap between the front and rear substrates can be as narrow as several millimeters or less. This serves to make the display lighter and thinner than cathode ray tubes (CRTs) that are used in combination with the computers available at present and in the television sets.

In most cases, the scanning-line drive circuit and the signal-line drive circuit are provided, one laid on the other, on the outer surface of the rear substrate or arranged on the peripheral edge thereof. This raises the following problems.

If the scanning-line drive circuit and the signal-line drive circuit are provided, one laid on the other, on the outer surface of the rear substrate, lines are guided from the drive circuits to the rear substrate for a long distances. Since the lines are provided in a flexible substrate including a tape carrier package (TCP), they are long. Further, the lines are likely to be cut, impairing the reliability of the display, because they are guided from the outer (reverse) side of the rear substrate to the inner surface thereof over the edge thereof. In this case, the module comprising the front substrate and the rear substrate become thick.

If the scanning-line drive circuit and the signal-line drive circuit are arranged on the peripheral edge of the rear substrate, the SED will have a broad frame-shaped region.

### BRIEF SUMMARY OF THE INVENTION

The present invention has been made in light of the above. An object of the invention is to provide a reliable display device that can be small and thin.

A display device according to an aspect of this invention comprises:

a first substrate which has a line-forming surface;

a second substrate which is arranged opposite to the line-forming surface by a gap interposed and has peripheral edge bonded to the first substrate;

a plurality of display elements which are provided between the first substrate and the second substrate;

a plurality of lines which are formed on the line-forming surface, extend to the peripheral edge of the line-forming surface and supply a drive voltage to the display elements; and

a drive circuit substrate which is arranged at the peripheral edge of the line-forming surface and on which drive circuit is mounted.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view showing an SED according to an embodiment of the present invention;

FIG. 2 is a sectional view of the SED, taken along line II-II shown in FIG. 1;

FIG. 3 is a sectional view of the SED, taken along line III-III shown in FIG. 1;

FIG. 4 is a plan view of a rear substrate, showing signal lines provided in a non-counter region shown in FIG. 3; and

FIG. 5 is a sectional view showing a modification of the SED illustrated in FIG. 3.

### DETAILED DESCRIPTION OF THE INVENTION

An embodiment, in which the display device of the invention is applied to an SED, will be described in detail with reference to the accompanying drawings.

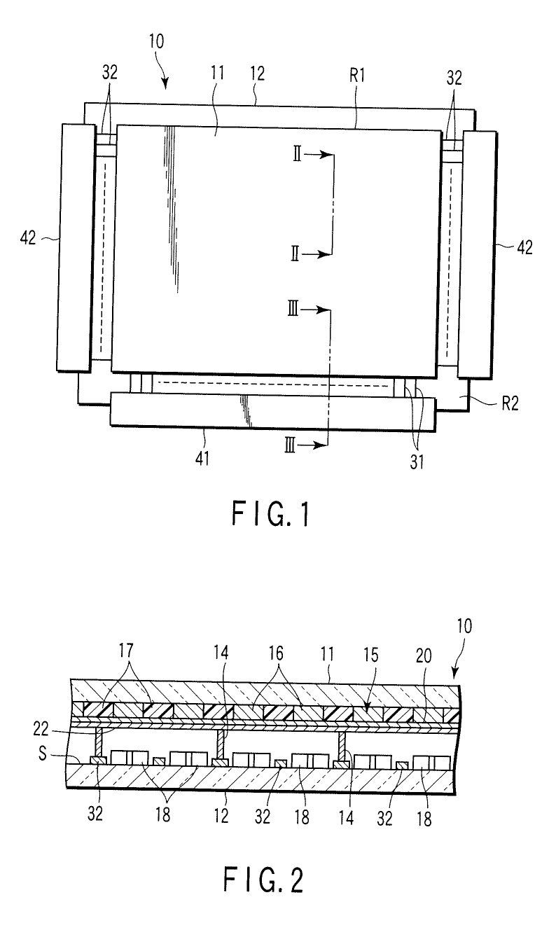

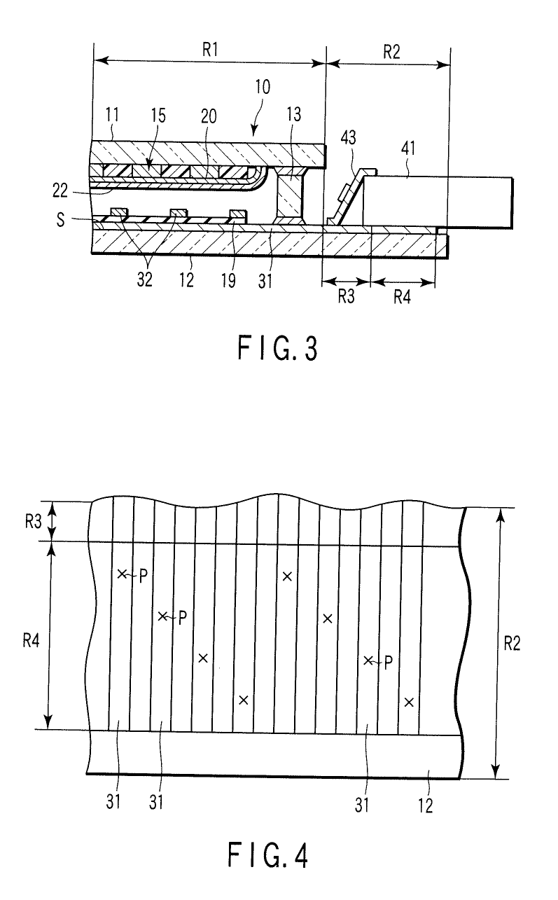

As shown in FIGS. 1 to 3, the SED comprises a front substrate 11 and rear substrate 12, which are rectangular glass plates used as insulating substrates. The rear substrate 12, or second substrate, is larger than the front substrate 11, or first substrate. The rear substrate 12 has a counter region R1 facing the front substrate 11 and a frame-shaped non-counter region R2 surrounding the counter region. The front substrate 11 and the counter region of the rear substrate 12 are opposed to each other with a predetermined gap between them.

The non-counter region R2 constitutes a part of the frame region of the SED. The front substrate 11 and the rear substrate 12 are bonded, at their peripheries, via a rectangular frame-shaped sidewall 13 interposed between them, providing a flat vacuum envelope 10, in which a vacuum is maintained.

In the vacuum envelope 10, a plurality of spacers 14 are provided, supporting the front substrate 11 and rear substrate 12, so that the substrates 11 and 12 may withstand the atmospheric pressure applied to them. The spacers 14 may be plate-like ones or columnar ones.

On the inner surface of the front substrate 11, a fluorescent screen 15 is provided as image display screen. The fluorescent screen 15 has fluorescent layers 16 of red, blue and green and a matrix-shaped light-shielding layer 17. The fluorescent layers 16 may shaped like stripes or dots. A metal-back layer 20 made of aluminum film or the like is provided on the fluorescent screen 15. Further, a getter film 22 is laid on the metal-back layer.

That surface of the rear substrate 12, which faces the front substrate 11, functions as a line-forming surface S. On the line-forming surface S, a number of electron emission elements 18 are provided, each being a source of electrons that can excite the fluorescent layers 16 of the fluorescent screen 15. The electron emission elements 18 are arranged in rows and columns, each provided for one pixel. Hence, each pixel has one electron emission element 18 and one fluorescent layer 16 and functions as a display element of this invention.

Each electron emission element 18 comprises an electron-emitting unit (not shown) and a pair of element electrodes that apply a voltage to the electron-emitting unit. On the line-forming surface S of the rear substrate 12, stripe-shaped signal lines 31, or first lines, and stripe-shaped scanning lines 32, or second lines, are arranged, forming a matrix pattern, to apply a drive voltage to the electron emission elements 18. The lines 31 and 32 have one end led outside from the vacuum envelope 10. In the counter region R1, the signal lines 31 and the scanning lines 32 are arranged in the form of a matrix via an insulation layer 19.

As described above, the signal lines 31 and the scanning lines extend to the non-counter region R2 of the line-forming surface S. An end of each signal line 31 formed on the non-counter region R2 of the line-forming surface S has a bonding region R3 located on an inner part of the rear substrate 12 and a probing region R4 located in an outer part of the rear substrate. An end of each scanning line 32 formed on the line-forming surface S of the non-counter region R2 has a bonding region (not shown) located on an inner part of the rear substrate 12 and a probing region (not shown) located in an outer part of the rear substrate.

On the peripheral part of the line-forming surface S of the rear substrate 12, that is, on the line-forming surface of the non-counter region R2, a signal-line drive circuit substrate 41 and pair of scanning-line drive circuit substrates 42 are arranged. A signal-line drive circuit is mounted on the signal-line drive circuit substrate 41. Two scanning-line drive circuits are mounted on the scanning-line drive substrates, respectively. More specifically, the signal-line drive circuit substrate 41 and the scanning-line drive circuit substrates 42 are connected to the line-forming surface of the non-counter region R2, using double-side adhesive tape (not shown) or the like.

The signal-line drive circuit substrate 41 is arranged, overlapping the probing regions R4 of the signal lines 31. The signal-line drive circuit on the signal-line drive circuit substrate 41 is electrically connected to a TCP 43. The TCP 43 is connected to the bonding region R3 of the signal lines 31, too. Therefore, the TCP 43 electrically connects the signal lines to the signal-line drive circuit.

Similarly, the scanning-line drive circuit substrates 42 (not shown) are arranged, one overlapping the other, in the probing region of the scanning lines 32. The scanning-line drive circuit on each scanning-line drive circuit substrate 42 is connected to the TCP via an anisotropic conductive film (ACF). The TCP is connected via the ACF to the bonding regions positioned at both ends of each scanning line 32. Therefore, the TCP electrically connects the scanning lines to the scanning-line drive circuit.

In the SED described above, the signal-line drive circuit and the scanning-line drive circuits are driven, thereby supplying drive signals to the signal lines 31 and the scanning lines 32, in order to display an image. An anode voltage is applied to the fluorescent screen 15 and the metal-back layer 20. The anode voltage accelerates the electrons emitted from the emission elements 18. The electrons accelerated are made to collide with the fluorescent screen. The fluorescent layers 16 of the fluorescent screen 15 are excited, displaying a color image.

The bonding regions and probing regions of the signal lines 31 and scanning lines 32 will be described, referring only to the bonding regions R3 and probing regions R4 of the signal lines.

The bonding regions R3 of the signal lines 31 are a region that connects the signal lines to the signal-line drive circuit. The probing regions R4 of the signal lines 31 are a region in which the signal-line drive circuit is arranged. The probing regions R4 are used, as will be described below, before the front substrate 11 and the read substrate 12 are combined together.

To form the rear substrate 12, the probing region R4 of the signal lines 31 is used in a food process. It is used in forming and inspecting the electron emission elements 18.

How the probing region R4 is used in the forming process performed on the electron emission elements 18 will be explained. Generally, to form electron emission elements, an electrically conductive thin film is first formed to connect the element electrodes of the electron emission elements. Next, the probes are contacted to the probing regions R4 of the signal lines 31 and the probing regions of the scanning lines 32. Thereafter, a voltage is applied to the signal lines 31 and the scanning lines 32 via the probes. The voltage is applied to the ends of the thin film, making cracks in the thin film. The forming process on the electron emission elements 18 is thereby completed.

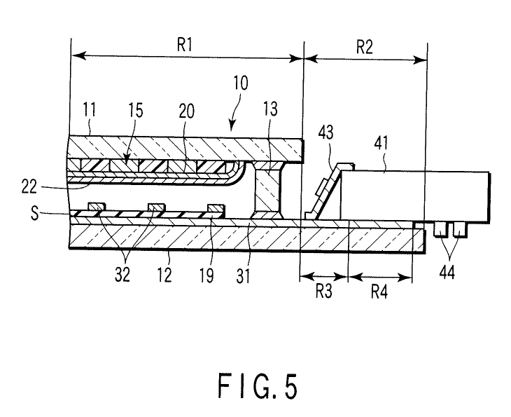

The probing regions of the signal lines 31 and the probing regions of the scanning lines 32 have a specific length each. As shown in FIG. 4, the probe-contact parts P contacting probes in the probing regions of the adjacent signal lines incline to the direction that intersects at right angles with the direction in which the signal lines extend. This is because the probing regions R4 of the adjacent signal lines 31 are spaced apart a little. Hence, the probing regions of the signal lines 31 and the probing regions of the scanning lines 32 need to have a specific length each.

In the SEC thus configured, the signal-line drive circuit substrate 41 and the scanning-line drive circuit substrates 42 lie on the peripheral edge of the line-forming surface S of the rear substrate 12. More precisely, they lie in the non-counter region R2 of the line-forming region. The signal-line drive circuit substrate is arrange, overlapping the probing regions R4 of the signal lines 31, and the scanning-line drive circuit substrates are arranged, overlapping the probing regions of the scanning lines 32.

The probing regions of the signal lines 31 and scanning lines 32 are used, only in forming and inspecting the electron emission elements 18. They are no longer necessary after the display has been produced. This is why the signal-line drive circuit substrate and the scanning-line drive circuit substrates can be arrange, one on another, in the probing regions.

If the TCP is guided around the peripheral edge of the rear substrate, the lines in the TCP will be likely to be cut. Nevertheless, such cutting of lines can be suppressed in the present embodiment. That is, the line can remain intact. This helps to enhance the reliability of the product.

The signal-line drive circuit and the scanning-line drive circuits are connected by the TCP 42 to the bonding regions of the signal lines 31 and the bonding regions of the scanning lines 32, respectively. The signal-line drive circuit and the scanning-line drive circuits may be provided on the outer surface of the rear substrate 12, one laid on another. In this case, the TCP must be guided around the peripheral edge of the rear substrate 12. The TCP 43 is inevitably shorter than in a TCP that is provided on the outer surface of the rear substrate 12. Since the TCP is an expensive component, the short TCP 43 can reduce the manufacturing cost of the product. Moreover, the short TCP 43 can increase the reliability of the product.

The SED according to this embodiment has a module thickness smaller than in the case where the signal-line drive circuit 41 and the scanning-line drive circuits 42 are provided on the outer surface of the rear substrate, one laid on another. Further, the frame-shaped sidewall is narrower than in the case where the signal-line drive circuit substrate 41 and the scanning-line drive circuit substrates 42 are provided, one laid on another, on the peripheral edge of the rear substrate 12. As indicated above, the signal-line drive circuit 41 and the scanning-line drive circuits 42 are provided in the non-counter region R2 of the line-forming surface S. The non-counter region of the line-forming surface is therefore covered. The peripheral edge of the rear substrate 12 can therefore have panel strength greater than in the case where neither the signal-line drive circuit substrate 41 nor the scanning-line drive circuit substrates 42 are provided.

The signal-line drive circuit substrate 41 and the scanning-line drive circuit substrates 42 are arranged, each extending outside the peripheral edge of the rear substrate 12. This prevents the product from being broken when a force is externally applied to the edge of the rear substrate. Thus, the signal-line drive circuit substrate 41 and the scanning-line drive circuit substrates 42 also have a function of protecting the edge of the rear substrate 12.

As has been described, this invention can provide an SED having high reliability and large panel strength, which can be made small and thin.

The present invention is not limited to the embodiment described above. Rather, various modifications and changes can be made within the scope of the invention. For example, as shown in FIG. 5, capacitors 44 may be provided, protruding from the outer surface of the signal-line drive circuit substrate 41 lying on the peripheral edge of the rear substrate 12. In place of the capacitors 44, connectors, inductors or the like may be provided. This can be applied to the scanning-line drive circuit substrates 42, too.

Only one scanning-line drive circuit substrate 42 may be used. If this is the case, the substrate 42 is connected to only one end of each scanning line 32. The connection scheme of this invention may be applied to the signal-line drive circuit substrate 41 or the scanning-line drive circuit substrates 42, or both.

The invention is not limited to SEDs. It can be applied to displays of other types, too, such as FEDs, plasma display panels (PDPs) and liquid crystal displays (LCDs) and the like.

What is claimed is:

1. A display device comprising:
a first substrate which has a line-forming surface;
a second substrate which is arranged opposite to the line-forming surface by a gap interposed and has peripheral edge bonded to the first substrate;
a plurality of display elements which are provided between the first substrate and the second substrate;
a plurality of lines which are formed on the line-forming surface, extend to the peripheral edge of the line-forming surface and supply a drive voltage to the display elements; and
a drive circuit substrate which is arranged at the peripheral edge of the line-forming surface and on which drive circuit is mounted.

2. The display device according to claim 1, wherein one end of each of the lines, which is located at a peripheral edge of the line-forming surface, has a bonding region located inside the line-forming surface and a probing region located outside the line-forming surface, and the drive circuit substrate is arranged, overlapping the probing region on the one end of each of the lines.

3. The display device according to claim 2, wherein the drive circuit is electrically connected to the bonding region on the one end of each of the lines.

4. A display device comprising:
a first substrate which has a counter region, a non-counter region and a line-forming surface provided in the counter region and the non-counter region;
a second substrate which is arranged opposite to the line-forming surface by a gap interposed and has peripheral edge bonded to the first substrate;
a plurality of display elements which are provided between the first substrate and the second substrate;
a plurality of signal lines and a plurality of scanning lines, which are arranged in the counter region of the line-forming surface, forming a matrix pattern, which extend to the non-counter region of the line-forming surface and which supply a drive voltage to the display elements; and
a signal-line drive circuit substrate which is arranged in the non-counter region of the ling-forming surface and on which a signal-line drive circuit is mounted, and a scanning-line circuit substrate which is arranged in the non-counter region and on which a scanning-line drive circuit is mounted.
